(19) United States
(12) Patent Application Publication
(10) Pub. No.: US 2007/0170426 A1
(43) Pub. Date: Jul. 26, 2007

(54) Silicon crystallizing mask, apparatus for crystallizing silicon having the mask and method for crystallizing silicon using the apparatus

(75) Inventor: Cheol-Ho Park, Gyeonggi-do (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/584,069

(22) Filed: Oct. 20, 2006

(30) Foreign Application Priority Data
Jan. 26, 2006 (KR) 2006-8058

(51) Int. Cl. H01L 29/04

(52) U.S. Cl. 257/49

(57) ABSTRACT

In a silicon crystallization mask that may be used to enhance electrical characteristics of silicon, an apparatus for crystallizing silicon having the mask and a method for crystallizing silicon using the apparatus, the mask includes first slits and second slits. The first slits are configured to transmit light and are arranged substantially parallel to one another along a first direction. The second slits transmit light, are separated by a predetermined distance along a second direction, and are arranged substantially parallel to one another along the first direction. Imaginary central lines of the first slits are offset from imaginary central lines of the second slits. Therefore, nuclei originated from a center portion of an area irradiated by the laser beam may be removed, and thus the electrical characteristics of silicon can be enhanced.

### CROSS-REFERENCE TO RELATED APPLICATIONS

The present application claims priority from Korean Patent Application No. 2006-0008058, filed on Jan. 26, 2006, the disclosure of which is hereby incorporated herein by reference in its entirety.

### BACKGROUND OF THE INVENTION

1. Field of the Invention

The present invention relates to a silicon crystallizing mask, an apparatus for crystallizing silicon having the mask and a method for crystallizing silicon using the apparatus. More particularly, the present invention relates to the silicon crystallizing mask for enhancing electrical characteristics of silicon, the apparatus for crystallizing silicon having the mask and the method for crystallizing silicon using the apparatus.

2. Description of the Related Art

Previously, liquid crystal displays (“LCDs”) typically used an amorphous silicon thin film transistor (a-Si TFT) as a switching element. More recently, to meet demands for high definition display quality, LCDs often use a poly crystalline silicon thin film transistor (poly-Si TFT), which has a fast operation speed. Particularly, poly-Si TFTs are predominantly used in organic light emitting display apparatus, which display images using circuit-driven organic light emitting diodes (“OLEDs”).

Methods for forming a poly-Si thin film in the poly-Si TFT include a method in which the poly-Si thin firm is formed directly on a substrate, a method forming the poly-Si thin film by heat treatment of an a-Si thin film formed on a substrate, etc. The heat treatment for this method is generally performed using a laser beam.

The heat treatment by the laser beam will be briefly described. A laser beam generated by a laser is irradiated onto the substrate and changes the a-Si TFT into a liquid state. Upon cooling, the liquefied silicon re-solidifies with a nucleus as the center, and is rearranged as plural grains having a superior crystalline quality. Thus, the a-Si thin film is transformed into poly-Si thin film having a high electrical conductivity.

The laser beam generated by the laser may be irradiated onto the substrate directly, but generally the laser beam is irradiated through a mask. In this case, the mask includes a plurality of slits transmitting the laser beam. The laser beam irradiated onto the substrate through the mask liquefies the a-Si thin film.

The a-Si thin film liquefied by the laser beam laterally uses the a-Si thin film in a solid state as a growth nucleus to grow crystal grains from side portions of the irradiated area to the center portion thereof. In this way, the a-Si thin film is transformed into the poly-Si thin film.

However, along with lateral growth, other grains may grow from nuclei in the center portion of the irradiated area. In some circumstances, the growth probability of nuclei in the center portion may increase, especially when a slit width of the mask is large. Crystal grains from nuclei in the center portion may crystallize with inferiority quality in the poly-Si thin film, and may lower the quality of the electrical characteristics of the resulting poly-Si thin film.

### SUMMARY OF THE INVENTION

Embodiments of the present invention provide a silicon crystallization mask for enhancing electrical characteristics of silicon by reducing or eliminating a nucleus growing up in a center portion.

Embodiments of the present invention also provide an apparatus for crystallizing silicon having the silicon crystallization mask.

Embodiments of the present invention also provide a method for crystallizing silicon using the silicon crystallization apparatus.

In an example silicon crystallization mask according to the present invention, the silicon crystallization mask includes first slits and second slits.

The first slits are configured to transmit light and are arranged parallel to one another along a first direction. The second slits are configured to transmit light, are separated by a predetermined distance along a second direction perpendicular to the first direction, and are arranged parallel to one another along the first direction, and at least some of the second slits are arranged between two adjacent first slits. The first slits have imaginary central lines along the second direction and the second slits have imaginary central lines along the second direction that is offset from the imaginary central lines of the first slits.

In an example apparatus to crystallize silicon according to embodiments of the present invention, the apparatus includes a laser generator part and a silicon crystallization mask.

The laser generator part generates a laser beam. The silicon crystallization mask partially transmits the laser beam and partially blocks the laser beam, irradiates the partially transmitted laser beam onto a substrate having amorphous silicon (a-Si) formed thereon, and transforms the amorphous silicon (a-Si) into poly silicon (poly-Si).

The silicon crystallization mask includes first slits configured to transmit the laser beam and are arranged in parallel along a first direction, and second slits configured to transmit the laser beam, are separated by a predetermined distance along a second direction perpendicular to the first direction, and are arranged substantially parallel to one another along the first direction, and at least some of the second slits being arranged between two adjacent first slits. The second slits have a second imaginary central line extending in the second direction. The first slits have a first imaginary central line extending in the second direction, and the imaginary central lines of the first slits are offset from the imaginary central lines of the second slits.

In an example method for crystallizing silicon according to embodiments of the invention, the method for crystallizing silicon includes providing a substrate having amorphous silicon formed thereon, irradiating a laser beam onto a partial area of the substrate through a mask and partially crystallizing the amorphous silicon, moving the mask a predetermined distance with respect to the substrate, and irradiating the laser beam onto the other partial area of the substrate through the mask and partially crystallizing the amorphous silicon.

The mask includes first slits configured to transmit the laser beam and are arranged in parallel along a first direction, and second slits configured to transmit the laser beam, are separated by a predetermined distance along a second direction perpendicular to the first direction, and are arranged substantially parallel to one another along the first direction, and at least some of the second slits being arranged between two adjacent first slits. The second slits have a second imaginary central line extending in the second direction. The first slits have a first imaginary central line extending in the second direction, and the imaginary central lines of the first slits are offset from the imaginary central lines of the second slits. Therefore, nuclei originated from a center portion of an area irradiated by the laser beam may be reduced or eliminated, so that the electrical characteristics can be enhanced.

### BRIEF DESCRIPTION OF THE DRAWINGS

The above and other features and advantages of the present invention will become more apparent by describing in detailed exemplary embodiments thereof with reference to the accompanying drawings, in which:

FIG. 1 is a conceptual view illustrating an apparatus for crystallizing silicon according to a first exemplary embodiment of the present invention;

FIG. 2 is a plan view illustrating a crystallizing process of silicon on a substrate by the silicon crystallizing apparatus in FIG. 1;

FIG. 3 is a plan view illustrating a silicon crystallization mask of the silicon crystallizing apparatus in FIG. 1;

FIG. 4 is an enlarged plan view illustrating portion ‘A’ in FIG. 3;

FIG. 5 is a simplified plan view illustrating a partially crystallized state of silicon obtained by irradiating the substrate using a laser beam transmitted through the silicon crystallization mask in FIG. 3;

FIG. 6 is a cross-sectional view taken along the line I-I′ of FIG. 5;

FIG. 7 is a plan view illustrating the partially crystallized state of silicon obtained by irradiating the substrate twice, moving the laser beam relative to the substrate over a predetermined distance;

FIG. 8 is a plan view illustrating the partially crystallized state of silicon using a conventional silicon crystallizing mask;

FIG. 9 is a plan view partially illustrating the silicon crystallization mask of an apparatus to crystallize silicon according to a second exemplary embodiment of the present invention;

FIG. 10 is a plan view partially illustrating the silicon crystallization mask of the apparatus to crystallize silicon according to a third exemplary embodiment of the present invention; and

FIG. 11 is a plan view partially illustrating the silicon crystallization mask of the apparatus to crystallizing silicon according to a fourth example embodiment of the present invention.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully describe the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention. The presence of a first element does not imply the need for a second or other additional element.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes, “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present invention will be described in detail with reference to the accompanied drawings.

### Example Embodiment 1 <Silicon Crystallizing Mask>

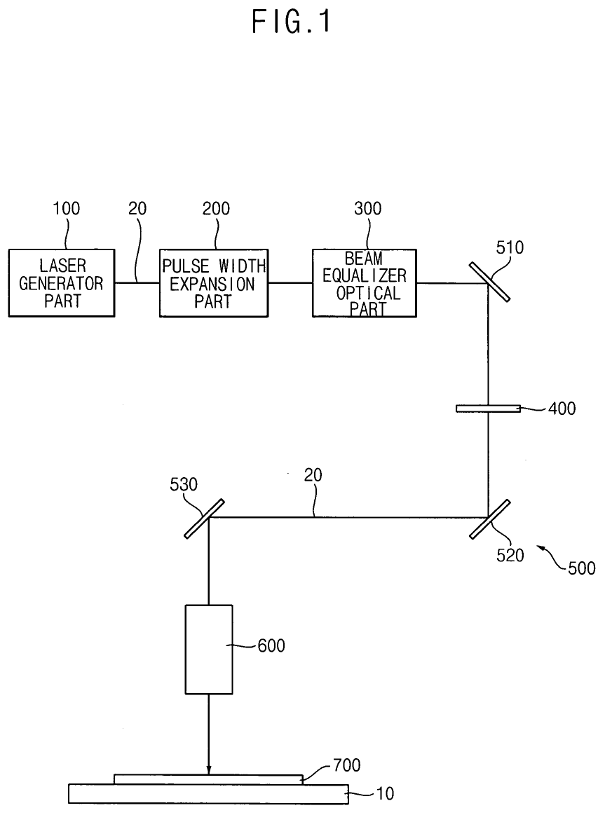

FIG. 1 is a conceptual view illustrating an apparatus for crystallizing silicon according to a first example embodiment of the present invention.

Referring to FIG. 1, the apparatus for crystallizing silicon according to the present embodiment includes a laser generator part 100, a pulse width expansion part 200, a beam equalizer optical part 300, a silicon crystallization mask 400, a beam reflector part 500 and a beam transmitter part 600.

The laser generator part 100 generates a laser beam 20 continuously or intermittently. For example, the laser generator part 100 generates an Excimer laser having a short wavelength, high power, and high efficiency laser beam 20.

In some embodiments, the wavelength of the laser beam 20 generated by the laser generator part 100 is, for example, in the range of about 300 nm to about 310 nm, and preferably about 308 nm. In this case, when a pulse frequency of the laser beam 20 is about 300 Hz, a pulse of the laser beam 20 is repeated about every 3.33 ms. For example, the pulse of the laser beam 20 is about 25 ns.

The pulse width expansion part 200 is disposed adjacent to the laser generator part 100, and expands a pulse width of the laser beam 20 generated by the laser generator part 100. Particularly, the pulse width expansion part 200 expands the pulse width about 10 times, from 25 ns to 250 ns. In the case where the pulse width of the laser beam 20 is expanded about 10 times, an energy density of the laser beam 20 is reduced about 10% to about 50%.

The pulse width expansion part 200, for example, includes a plurality of optical plates that transmit and reflect the laser beam 20. The optical plates delay a transmitted laser beam 20 and a reflected laser beam 20 by a predetermined time to combine with each other, and thus expand the pulse width of the laser beam 20.

The beam equalizer optical part 300 is disposed adjacent to the pulse width expansion part 200, and its goal is to equalize the distribution of energy according to the position of the laser beam exiting the pulse width expansion part 200. In general, the energy density of one pulse in the laser beam 20 has a Gaussian distribution. The beam equalizer optical part 300 changes the Gaussian distribution into a more uniform distribution (such as a square wave with a substantially constant energy density across the beam).

The beam equalizer optical part 300, for example, includes a plurality of division lenses. The division lenses divide the laser beam 20 into a plurality of sub-laser beams. Each division lens divides the laser beam 20 to generate a plurality of sub-laser beams, and mixes the sub-laser beams to better equalize the density distribution of energy.

The silicon crystallization mask 400 partially transmits and partially blocks the laser beam 20 that is received from the beam equalizer optical part 300. The silicon crystallization mask 400 irradiates the partially transmitted laser beam 20 onto a substrate 700 having an amorphous silicon (a-Si) material formed thereon. The transmitted portion of laser beam 20 crystallizes a-Si to transform at least some of the a-Si into poly silicon (poly-Si).

The beam reflector part 500 changes a path of the laser beam 20. The beam reflector part 500 includes a first reflecting mirror 510, a second reflecting mirror 520 and a third reflecting mirror 530.

The first reflecting mirror 510 is disposed between the beam equalizer optical part 300 and the silicon crystallization mask 400. The first reflecting mirror 510 reflects the laser beam 20 that exits the beam equalizer optical part 300 and guides the laser beam 20 to be incident into the silicon crystallization mask 400.

The second reflecting mirror 520 is disposed to receive laser beam 20 from the silicon crystallization mask 400 and reflects the laser beam 20 that has passed through the silicon crystallization mask 400 into the third reflecting mirror 530.

The third reflecting mirror 530 separated from the second reflecting mirror 520 by a predetermined distance, and reflects the laser beam 20 that has been reflected by the second reflecting mirror 520 towards the beam transmitter part 600. In this embodiment, in order to enhance optical characteristics of the laser beam 20, a plurality of lenses (not shown) and a plurality of mirrors (not shown) may be arranged between the second and third reflecting mirrors 520 and 530.

The beam transmitter part 600 is disposed to receive light from the third reflecting mirror 530, and is configured to change a size of the laser beam 20 that has been reflected from the third reflecting mirror 530, and irradiates the laser beam 20 onto the substrate 700. The beam transmitter part 600, for example, reduces the size of the laser beam 20 to about one fifth of its size as received by beam transmitter part 600. For example, the beam transmitter part 600 reduces the size of the laser beam 20 and irradiates the reduced laser beam 20 onto the substrate 700.

Here, the substrate 700 is disposed on a stage 10 and is supported by the stage 10. The stage 10 may be moved to a predetermined position by a substrate feed gear (not shown). According to movement of the stage 10 by the substrate feed gear, the silicon crystallization mask 400 moves relative to the substrate 700. Therefore, the laser beam that has passed through the silicon crystallization mask 400 is irradiated onto the entire area of substrate 700 to transform all the a-Si into poly-Si.

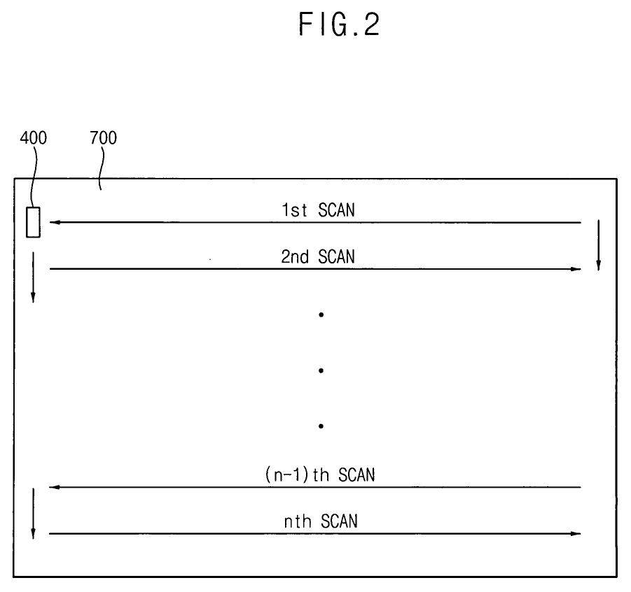

FIG. 2 is a plan view illustrating a process for crystallizing silicon on a substrate that may be performed by the apparatus for crystallizing silicon illustrated in FIG. 1.

Referring to FIG. 2, the silicon crystallization mask 400 repeatedly moves up and down, left and right relative to the substrate 700. For example, the position of the laser beam 20 irradiated onto the substrate through the silicon crystallizing mask 400, is moved up and down, left and right repeatedly (e.g., in a raster scan pattern).

Particularly, a first scan is performed with the silicon crystallizing mask 400 moving from a left edge to a right edge of the substrate 700 for a first interval distance. For example, in the first scan, the laser beam 20 that has passed through the silicon crystallization mask 400 moves from a position near the left edge of the substrate for a distance equal to the first interval, and in doing so passes over the right edge of the substrate 700. In the scanning operation, the laser beam 20 is intermittently irradiated on substrate 700.

After the first scan, the silicon crystallization mask 400 moves a second interval distance in a perpendicular direction to the scan direction. For example, the laser beam 20 that is being irradiated onto the substrate 700 moves a distance equal to the second interval in a perpendicular direction to the scan direction.

Then, a second scan is performed with the silicon crystallization mask 400 moving from the right edge to the left edge of the substrate 700 for the first interval. In the second scan, the laser beam 20 that has passed through the silicon crystallization mask 400 moves from the right edge to the left edge of the substrate 700, and the laser beam 20 is intermittently irradiated on the substrate 700.

After the second scan, the silicon crystallizing mask 400 again moves for a distance equal to the second interval in a perpendicular direction to the scan direction. In other words, the laser beam 20 that is being irradiated onto the substrate 700 moves a distance equal to the second interval in a perpendicular direction to the scan direction.

The process is repeated through performance of an N^{th} scan. During the course of the scanning operation, the laser beam 20 that has passed through the silicon crystallization mask 400 is repeatedly moved and returned from the right edge to the left edge of the substrate 700 (for a total of N scans). Upon completion of the N^{th} scan, the laser beam 20 that has passed through the silicon crystallization mask 400 has irradiated the entire substrate. Therefore, all the a-Si formed on the substrate 700 is crystallized and transformed into poly-Si.

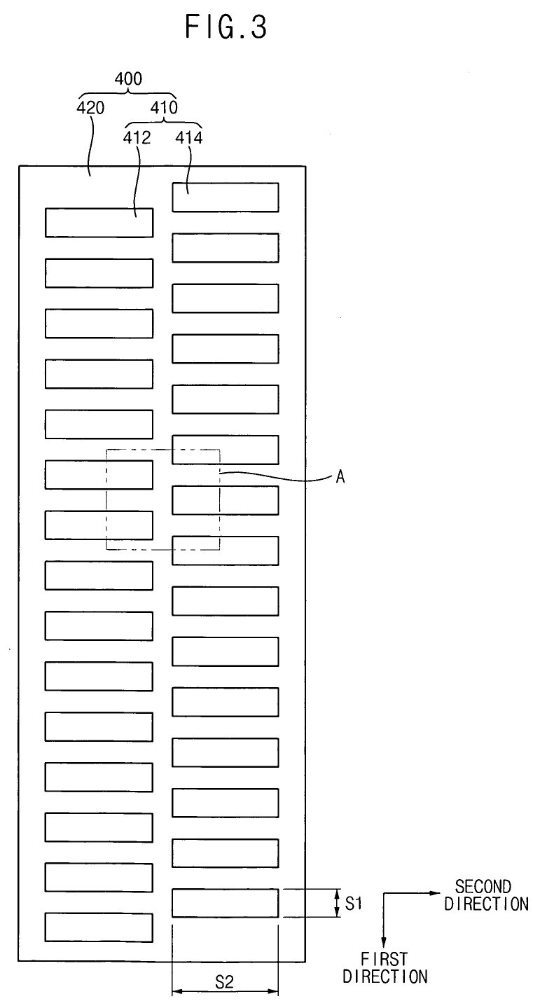

FIG. 3 is a plan view illustrating a silicon crystallization mask of the apparatus for crystallizing silicon in FIG. 1.

Referring to FIG. 3, the silicon crystallization mask 400 according to the present exemplary embodiment, when viewed on a plan, includes a transmissive part 410 and a blocking (non-transmissive) part 420. The transmissive part 410 transmits the laser beam 20, and the blocking part 420 blocks the laser beam 20. For example, the size of the silicon crystallizing mask 400 is about 125 mm×6 mm.

In some embodiments, the blocking part 420 includes a metallic material blocking the laser beam 20, and preferably includes chromium (Cr). In this embodiment, the transmissive part 410 is defined as a region where the blocking part 420 is not formed.

The transmissive part 410 includes a plurality of first slits 412 and a plurality of second slits 414 both configured to transmit the laser beam 20. The first slits 412 are arranged in parallel along a first direction. The second slits 414 are separated from the first slits 412 by a predetermined distance along a second direction perpendicular to the first direction, and are arranged in parallel along the first direction. Each of the second slits 414 is arranged between two adjacent first slits 412, or proximate an end slit of the first slits 412.

In the example illustrated in FIG. 3, each of the first and second slits 412, 414 has a rectangular shape. Alternatively, each of the first and second slits 412, 414 may have a different shape capable of inducing crystal growth differently. The rectangular shape has a first length S1 along the first direction, and a second length S2 along the second direction. For example, the first length S1 is in the range of about 25 μm to about 35 μm, and the second length S2 is in the range of about 2800 μm to about 3500 μm. Preferably, the first length S1 is about 27.5 μm and the second length S2 is about 3000 μm.

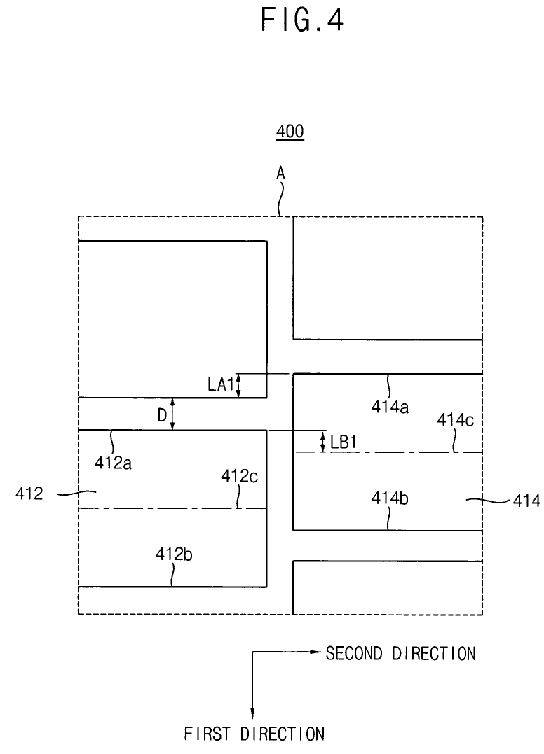

FIG. 4 is an enlarged plan view illustrating a portion ‘A’ in FIG. 3. FIG. 4 shows portions of two first slits 412 and three second slits 414. In the following, a number of lines are referred to in order to describe the relative positions of first slits 412 and second slits 414 in the illustrated embodiment. However, the lines need not refer to actual structure (such as the physical boundaries of first and second slits 412 and 414).

Referring to FIG. 4, each of the first and second slits 412, 414 has a rectangular shape. An interval D between the first slits 412 is in the range of about 2.5 μm to about 10 μm, and is preferably about 7.5 μm. An interval between the second slits 414 is the same as the interval D between the first slits 412. Therefore, an interval between the laser beams 20 that have passed through the first and second slits 412, 414 and are irradiated onto the substrate 700, is reduced to about one fifth of the interval D between the first slits 412; that is, reduced to about 1.5 μm in the described embodiment.

A first upper line 412a extends along an upper edge of the first slits 412 in the second direction, and is substantially perpendicular to edges of the first slits 412 that extend in the first direction. A first lower line 412b extends along a lower edge of the first slits 412 in the second direction, and is also substantially perpendicular to edges of the first slits 412 that extend in the first direction. A first central line 412c, extends in the second direction along centers of the first slits 412 between the first upper line 412a and the first lower line 412b.

In addition, a second upper line 414a extends long an upper edge of the second slits 414 in the second direction, and is substantially perpendicular to edges of the second slits 414 that extend in the first direction. A second lower line 414b extends along a lower edge of the second slits 414 in the second direction, and is also substantially perpendicular to edges of the second slits 414 that extend in the first direction. A second central line 414c extends in the second direction along centers of the second slits 414 between the second upper line 414a and the second lower line 414b. The first central line 412c and the second central line 414c divides the first and second slits into substantially equal areas. For the illustrated example, in which the first slits 412 and second slits 414 are rectangular, first central line 412c and second central line 414c also bisect the short side of the rectangle.

In this exemplary embodiment, the second central line 414c for a second slit 414 extends between the upper line 412a and the first central line 412c of an associated first slit 412.

Here, a first overlap distance LA1 is defined as a distance between a first lower line 412b and the adjacent second upper line 414a. The second overlap distance LB1 is defined as a distance between a first upper line 412a and the adjacent second central line.

In this exemplary embodiment, the first overlap distance LA1 is the same as the second overlap distance LB1. For example, when the first length S1 of the first slits 412 and the second slits 414 is about 27.5 μm and the interval D between adjacent first slits 412 and adjacent second slits 414 is about 7.5 μm, the first and second overlap distance LA1 and the second overlap distance LB1 are both about 6.25 μm.

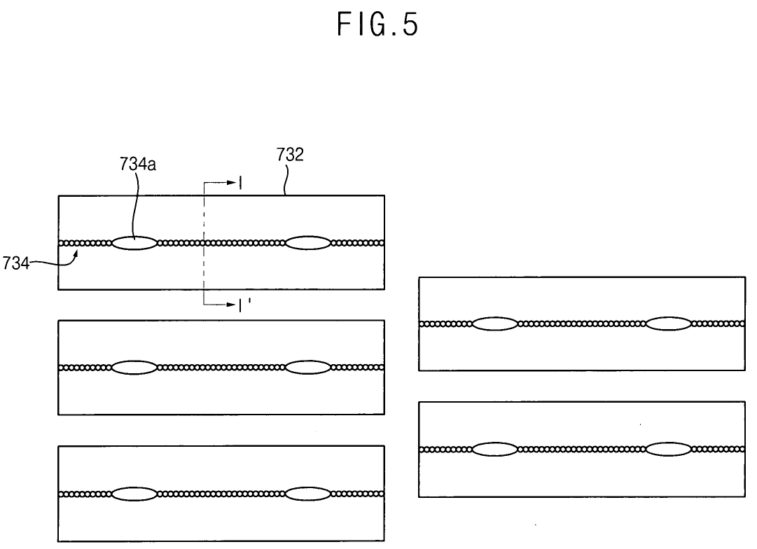

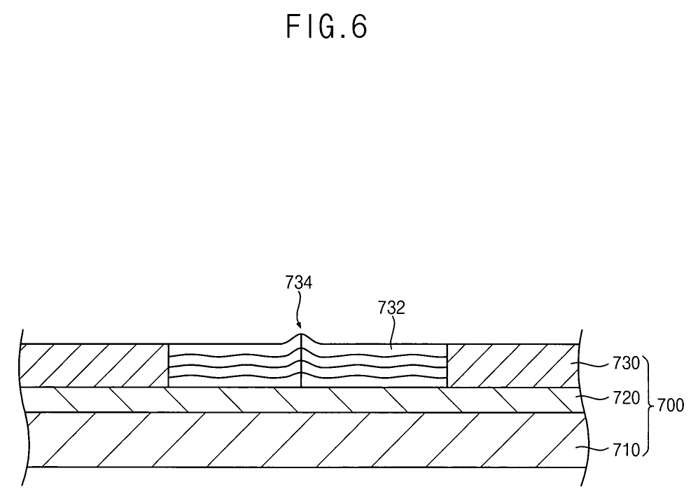

FIG. 5 is a plan view simplified illustrating a partially crystallized state of silicon induced by transmitting a laser beam through a mask such as the silicon crystallization mask in FIG. 3 onto the substrate, and FIG. 6 is a cross-sectional view taken along a line I-I′ of FIG. 5.

Referring to FIGS. 5 and 6, the laser beam 20 that has passed through the silicon crystallization mask 400 irradiates the substrate 700 to partially crystallize an a-Si layer 730. In the illustrated embodiment, the substrate 700 includes a base substrate 710, a silicon protective layer 720 and the a-Si layer 730. The base substrate 710, for example, includes a transparent material such as glass or quartz. The silicon protective layer 720 is formed between the a-Si layer 730 and the base substrate 710, and protects the a-Si layer 730.

When the laser beam 20 is incident on the substrate 700, the a-Si layer 730 is partially melted and subsequently re-solidifies with lateral crystal growth. For example, the melted silicon layer uses a non-melted a-Si layer as the growth nucleus. The crystal grows laterally from the growth nucleus. Poly-Si 732 is crystallized and a crystal protrusion 734 having a predetermined height is formed in a center of the poly-Si 732. The crystal protrusion 734 is formed along a longitudinal direction of the crystallized poly-Si 732.

In general, while the melted silicon layer regrows laterally from nuclei in the un-melted a-Si, other nuclei may be generated at a center portion of a region onto which the laser beam is irradiated. When these other nuclei grow to a predetermined size, a poorly crystallized portion 734a is formed in the crystallized poly-Si 732. The poorly crystallized portion 734a is generally formed along a longitudinal direction of the crystal protrusion 734. The poorly crystallized portion 734a is characterized by, for example, smaller grain size in comparison to regions of the polysilicon with higher crystal quality.

The crystal protrusion 734 and the poorly crystallized portion 734a lead to degraded electrical characteristics of the poly-Si 732, such as decreased electron mobility. Particularly, the electrical characteristics of the poly-Si 732 may be degraded more by the poorly crystallized portion 734a than the crystal protrusion 734.

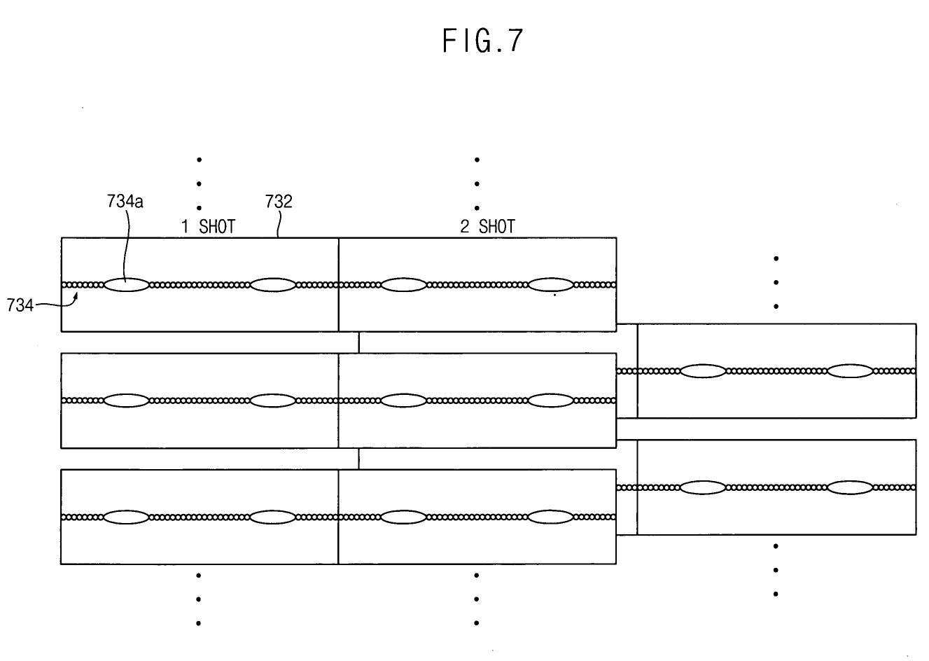

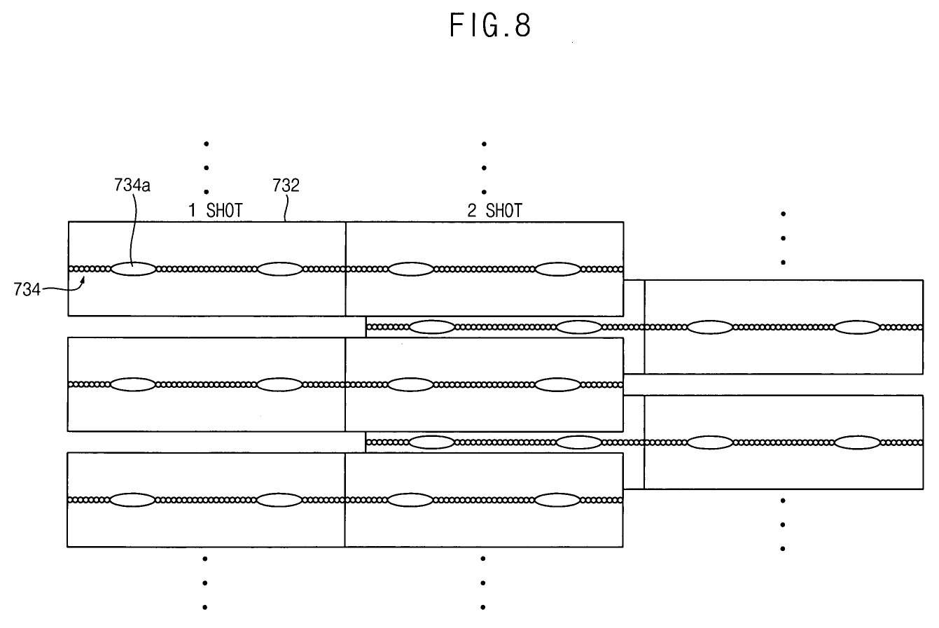

FIG. 7 is a plan view illustrating a partially crystallized state of silicon obtained by irradiating the substrate twice using a laser beam moving a predetermined distance relative to the substrate. FIG. 8 is a plan view illustrating a partially crystallized state of silicon using a conventional silicon crystallizing mask.

Referring to FIG. 7, the substrate 700 is irradiated by laser beam 20 over the predetermined distance more than one time, so that the crystal protrusion 734 and the poorly crystallized portion 734a are partially removed (e.g., re-melted and re-crystallized as higher quality polysilicon).

For example, the laser beam 20 that has passed through the silicon crystallization mask 400 is initially irradiated onto the substrate 700 to form a first poly-Si configuration referred to as 1 SHOT. In this case, the crystal protrusion 734 and the poorly crystallized portion 734a are formed at a center region of the first poly-Si 1 SHOT.

Then, the laser beam 20 that has passed through the silicon crystallization mask 400 moves over the predetermined distance and is subsequently irradiated onto the substrate 700. A second poly-Si configuration referred to as 2 SHOT is formed as a result of the second irradiation of the substrate 700 with laser beam 20. In this case, since the second central line 414c of each second slit 414 is positioned between the upper line 412a and the first central line 412c of each slit 412, the secondly irradiated laser beam 20 remelts and recrystallizes the crystal protrusion 734 and the poorly crystallized portion 734a formed along the second central line 414c. Therefore, the subsequent irradiation of substrate 700 by laser beam 20 (at least partially) removes the crystal protrusion 734 and the poorly crystallized portion 734a formed along the second central line 414c.

However, FIG. 8 illustrates that even if the substrate 700 is repeatedly irradiated using the laser beam transmitted through a conventional silicon crystallization mask, the crystal protrusion 734 and the poorly crystallized portion 734a formed along the second central line 414c are not removed. This is due to the fact that using the conventional silicon crystallization mask, the second central line 414c of each second slit 414 is formed along centers of the first slits 412.

Therefore, in the present exemplary embodiment, since the second central line 414c of each second slit 414 is formed between the upper line 412a and the first central line 412c of an associated first slit 412, repeatedly irradiating substrate 700 with the laser beam 20 may (fully or partially) remove the crystal protrusion 734 and the poorly crystallized portion 734a formed along the second central line 414c.

### Example Embodiment 2 <Silicon Crystallizing Mask>

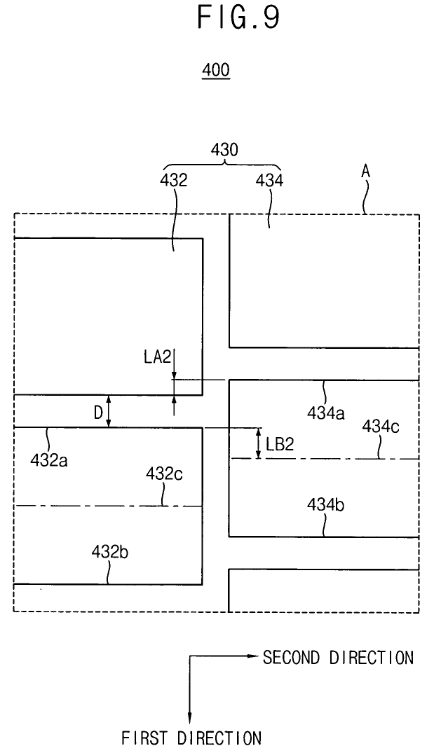

FIG. 9 is a plan view partially illustrating the silicon crystallization mask of an apparatus for crystallizing silicon according to a second exemplary embodiment of the present invention. The apparatus for crystallizing silicon according to the second exemplary embodiment of the present invention is the same as in the above-described apparatus for crystallizing silicon according to the first exemplary embodiment, except for the silicon crystallization mask. Thus, the same reference numerals will be used to refer to the same or like parts as those described in the above-described embodiment and further repetitive explanation concerning the above elements may be omitted.

Referring to FIG. 9, the silicon crystallization mask 400 according to the present exemplary embodiment, when viewed on a plan, includes a transmissive part 430 and a non-transmissive (blocking) part 420. A laser beam passes through the transmissive part 430 and is blocked by the blocking part 420. The transmissive part 430 is defined as a region where the blocking part 420 is not formed.

The transmissive part 430 includes a plurality of first slits 432 and a plurality of second slits 434 configured to transmit the laser beam 20. The first slits 432 are arranged parallel to one another and positioned along a first direction. The second slits 434 are separated from the first slits 432 by a predetermined distance along a second direction perpendicular to the first direction, and are arranged parallel to one another and positioned along the first direction, and each of the second slits 434 is arranged between two adjacent first slits 432.

As illustrated in FIG. 9, each of the first and second slits 432, 434 has a rectangular shape. An interval D between adjacent first slits 432 and adjacent second slits 434 is in the range of about 2.5 μm to about 10 μm, and is preferably about 7.5 μm.

A first upper line 432a corresponds to an upper edge of a first slit 432, and a first lower line 432b corresponds to a lower edge of the first slit 432. FIG. 9 illustrates a first central line 432c extending in the second direction along the centers of the first slits 432, and is positioned between the first upper line 432a and the first lower line 432b. In addition, a second upper line 434a corresponds to an upper edge of a second slit 434, and a second lower line 434b corresponds to a lower edge of the second slit 434. A second central line 434c is illustrated extending in the second direction along the center of the second slit 434, and is positioned between the second upper line 434a and the second lower line 434b.

In this exemplary embodiment, first slits 432 and second slits 434 are positioned so that the second central line 434c is positioned between the upper line 432a and the first central line 432c of the associated first slit 432.

A first overlap distance LA2 is defined as a distance between the first lower line 432b and the adjacent second upper line 434a. The second overlap distance LB2 is defined as a distance between the first upper line 432a and the adjacent second central line 434c.

In this exemplary embodiment, the first overlap distance LA2 is greater than the second overlap distance LB2. For example, the first overlap distance LA2 is in the range of about 1.6 μm to about 2.9 μm, and the second overlap distance LB2 is in the range of about 0.1 μm to about 1.4 μm. Preferably, when the first overlap distance LA2 is about 1.6 μm, the second overlap distance LB2 is about 1.4 μm, and when the first overlap distance LA2 is about 2.9 μm, the second overlap distance LB2 is about 0.1 μm.

Here, the second overlap distance LB2 is preferably at least about 0.1 μm. When the second overlap distance LB2 is less than 0.1 μm, the distance is within a margin of error of the apparatus for crystallizing silicon. Therefore, although the laser beam 20 is repeatedly irradiated as illustrated in FIG. 7 and described above, the crystal protrusion 734 and the poorly crystallized portion 734a formed along the second central line 434c may not be adequately removed, due to the characteristics of the apparatus for crystallizing silicon.

### Exemplary Embodiment 3 <Silicon Crystallizing Mask>

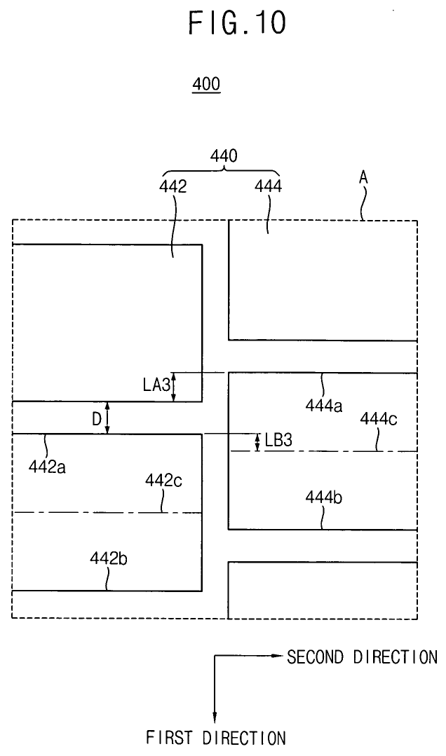

FIG. 10 is a plan view partially illustrating the silicon crystallization mask of the apparatus for crystallizing silicon according to a third exemplary embodiment of the present invention. The apparatus for crystallizing silicon according to the third exemplary embodiment of the present invention is the same as in the above-described apparatus for crystallizing silicon according to the first exemplary embodiment, except for aspects of the silicon crystallization mask. Thus, the same reference numerals will be used to refer to the same or like parts as those in the above-described embodiment, and further repetitive explanation concerning the above elements may be omitted.

Referring to FIG. 10, the silicon crystallization mask 400 according to the present exemplary embodiment, when viewed on a plan, includes a transmissive part 440 and a non-transmissive (blocking) part 420. The laser beam 20 passes through the transmissive part 440 and is blocked by the blocking part 420. In the embodiment of FIG. 10, the transmissive part 440 is implemented as a region where the blocking part 420 is not formed.

The transmissive part 440 includes a plurality of first slits 442 and a plurality of second slits 444 transmitting the laser beam 20. The first slits 442 are parallel to one another and arranged along the first direction. The second slits 444 are separated from the first slits 442 by a predetermined distance along a second direction perpendicular to the first direction, and are parallel to one another and arranged along the first direction. Each of the second slits is arranged between two adjacent first slits 442.

Each of the first and second slits 442, 444 has a rectangular shape. An interval D between adjacent first slits 442 and adjacent second slits 444 is in the range of about 2.5 μm to about 10 μm, and is preferably about 7.5 μm.

A first upper line 442a corresponds to an upper edge of a first slit 442, and a first lower line 442b corresponds to a lower edge of the first slit 442. First upper line 442a and first lower line 442b are substantially perpendicular to the first direction. A first central line 442c extends in the second direction along centers of the first slits 442, and is arranged between the first upper line 442a and the first lower line 442b. In addition, a second upper line 444a corresponds to an upper edge of a second slit 444, and a second lower line 444b corresponds to a lower edge of the second slit 444. Second upper line 444a and second lower line 444b are substantially perpendicular to the first direction. A second central line 444c extends in the second direction along centers of the second slits 444, and is arranged between the second upper line 444a and the second lower line 444b.

In this exemplary embodiment, the first slits 442 and second slits 444 are formed so that second central line 444c is positioned between the upper line 442a and the first central line 442c of the first slits 442.

A first overlap distance LA3 is defined as a distance between the first lower line 442b and the adjacent second upper line 444a. The second overlap distance LB3 is defined as a distance between the first upper line 442a and the adjacent second central line 444c.

In this exemplary embodiment, the first overlap distance LA3 is less than the second overlap distance LB3. For example, the first overlap distance LA3 is in the range of about 0.1 μm to about 1.4 μm, and the second overlap distance LB3 is in the range of about 1.6 μm to about 2.9 μm. Preferably, when the first overlap distance LA3 is about 1.4 μm, the second overlap distance LB3 is about 1.6 μm, and when the first overlap distance LA3 is about 0.1 μm, the second overlap distance LB3 is about 2.9 μm.

In this embodiment, the first overlap distance LA3 is preferably at least about 0.1 μm to be greater than a margin of error of the silicon crystallizing apparatus.

### Exemplary Embodiment 4 <Silicon Crystallization Mask>

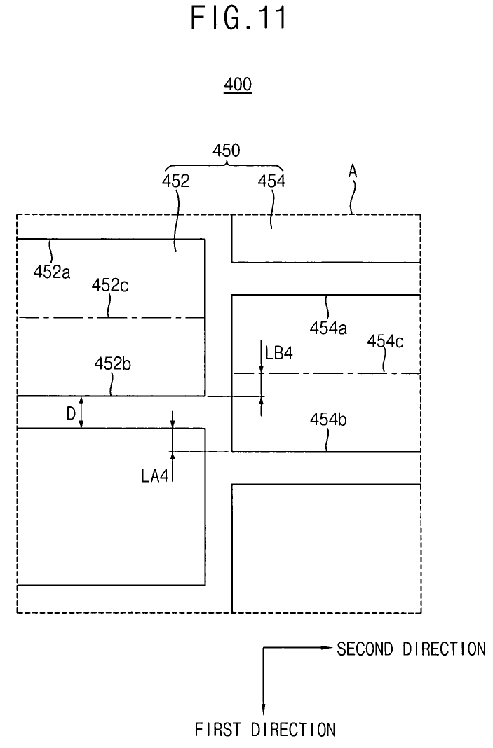

FIG. 11 is a plan view partially illustrating the silicon crystallization mask of the apparatus for crystallizing silicon according to a fourth exemplary embodiment of the present invention. The apparatus for crystallizing silicon according to the fourth exemplary embodiment of the present invention is the same as in the above-described apparatus for crystallizing silicon according to the first exemplary embodiment, except for the silicon crystallization mask. Thus, the same reference numerals will be used to refer to the same or like parts as those used in the above-described embodiment and further repetitive explanation concerning the above elements may be omitted.

Referring to FIG. 11, the silicon crystallization mask 400 according to the present embodiment, when viewed on a plan, includes a transmissive part 450 and a non-transmissive (blocking) part 420. The laser beam 20 passes through the transmissive part 450 and is blocked by the blocking part 450. In the embodiment of FIG. 11, the transmissive part 450 is defined as a region where the blocking part 420 is not formed.

The transmissive part 450 includes a plurality of first slits 452 and a plurality of second slits 454 transmitting the laser beam 20. The first slits 452 are parallel to one another and arranged along the first direction. The second slits 454 are separated from the first slits 452 by a predetermined distance along a second direction perpendicular to the first direction, and are parallel to one another and arranged along the first direction. Each of the second slits 454 is arranged between two adjacent first slits 452.

Each of the first and second slits 452, 454 has a rectangular shape. An interval D between the first slits 452 and the second slits 454 is in the range of about 2.5 μm to about 10 μm, and is preferably about 7.5 μm.

A first upper line 452a corresponds to an upper edge of a first slit 452, and a first lower line 452b corresponds to a lower edge of the first slit 452. First upper line 452a and first lower line 452b are substantially perpendicular to the first direction. A first central line 452c extends in the second direction along centers of first slits 452, and is arranged between the first upper line 452a and the first lower line 452b. In addition, a second upper line 454a corresponds to an upper edge of a second slit 454, and a second lower line 454b corresponds to a lower edge of the second slit 454. Second upper line 454a and second lower line 454b are substantially perpendicular to the first direction among edges of each of the second slits 454. A second central line 454c extends in the second direction along centers of second slits 454, and is arranged between the second upper line 454a and the second lower line 454b.

In this exemplary embodiment, the second central line 454c is formed between the lower line 452b and the first central line 452c of the first slits 452.

A first overlap distance LA4 is defined as a distance between the first upper line 452a and the adjacent second lower line 454b. The second overlap distance LB4 is defined as a distance between the first lower line 452a and the adjacent second central line 454c.

In this exemplary embodiment, the first overlap distance LA4 is the same as the second overlap distance LB4. Alternatively, the first overlap distance LA4 may be greater than or less than the second overlap distance LB4.

When the first overlap distance LA4 is the same as the second overlap distance LB4, the distance is, for example, preferably about 6.25 μm.

Alternatively, when the first overlap distance LA4 is greater than the second overlap distance LB4, the first overlap distance LA4 may be in the range of about 1.6 μm to about 2.9 μm and the second overlap distance LB4 is in the range of about 0.1 μm to about 1.4 μm. When the first overlap distance LA4 is less than the second overlap distance LB4, the first overlap distance LA4 may be in the range of about 0.1 μm to about 1.4 μm and the second overlap distance LB4 is in the range of about 1.6 μm to about 2.9 μm.

According to embodiments of the present invention of the silicon crystallization mask, the crystal protrusion and the poorly crystallized portion formed along the second central line may be partially or entirely removed by repeatedly irradiating the substrate using the laser beam, as described more fully above. Therefore, the electrical characteristics of the poly-Si and a display quality of a display apparatus may be enhanced.

Having described the exemplary embodiments of the present invention and its advantages, it is noted that various changes, substitutions and alterations can be made herein without departing from the spirit and scope of the invention as defined by appended claims.

What is claimed is:

1. A silicon crystallization mask comprising:
a plurality of first slits configured to transmit incident light, wherein the plurality of first slits are arranged along a first direction and are substantially parallel to one another, and wherein an imaginary central line of each of the first slits along a second direction perpendicular to the first direction divides the associated first slit into two substantially equal areas; and
a plurality of second slits configured to transmit incident light, the plurality of second slits separated from the plurality of first slits by a predetermined distance along a second direction perpendicular to the first direction, wherein the plurality of second slits are arranged along the first direction and are substantially parallel to one another, wherein an imaginary central line of each of the second slits along the second direction divides the associated second slit into two substantially equal areas, and wherein the plurality of second slits is positioned so that the central line of each of the plurality of second slits is offset from the central line of at least one adjacent first slit.

2. The silicon crystallization mask of claim 1, wherein each of the first slits has a rectangular shape and includes a first upper edge along a first upper line extending in the second direction and a first lower edge along a first lower line extending in the second direction;
wherein each of the second slits has a rectangular shape and includes a second upper edge along a second upper line extending in the second direction and a second lower edge along a second lower line extending in the second direction.

3. The silicon crystallization mask of claim 2, wherein the second central line of a particular second slit is positioned between a first upper line and a first central line of a particular first slit adjacent the particular second slit, a distance between the first lower line of the particular first slit and the second upper line of a next second slit adjacent the particular second slit is a first overlap distance, and a distance between the first upper line of the particular first slit and the second central line of the particular second slit is a second overlap distance.

4. The silicon crystallization mask of claim 3, wherein the first overlap distance and the second overlap distance are the same.

5. The silicon crystallization mask of claim 3, wherein the first overlap distance is greater than the second overlap distance.

6. The silicon crystallization mask of claim 5, wherein the first overlap distance is in the range of about 1.6 μm to about 2.9 μm and the second overlap distance is in the range of about 0.1 μm to about 1.4 μm.

7. The silicon crystallization mask of claim 3, wherein the first overlap distance is less than the second overlap distance.

8. The silicon crystallization mask of claim 7, wherein the first overlap distance is in the range of about 0.1 μm to about 1.4 μm and the second overlap distance is in the range of about 1.6 μm to about 2.9 μm.

9. The silicon crystallization mask of claim 2, wherein a particular second slit is positioned so that a second central line of the particular second slit is between the first lower line and the first central line of a particular first slit adjacent the particular second slit, a distance between the first upper line of a next first slit adjacent the particular first slit and the second lower line of the particular second slit is a first overlap distance, and a distance between the first lower line of the particular first slit and the second central line of the particular second slit is a second overlap distance.

10. The silicon crystallization mask of claim 9, wherein the first overlap distance and the second overlap distance are the same.

11. The silicon crystallization mask of claim 9, wherein the first overlap distance is greater than the second overlap distance.

12. The silicon crystallization mask of claim 11, wherein the first overlap distance is in the range of about 1.6 μm to about 2.9 μm and the second overlap distance is in the range of about 0.1 μm to about 1.4 μm.

13. The silicon crystallization mask of claim 9, wherein the first overlap distance is less than the second overlap distance.

14. The silicon crystallization mask of claim 13, wherein the first overlap distance is in the range of about 0.1 μm to about 1.4 μm and the second overlap distance is in the range of about 1.6 μm to about 2.9 μm.

15. The silicon crystallization mask of claim 2, wherein each of the first slits has a first length along the first direction and a second length along the second direction, and wherein the first length of each of the first slits is in the range of about 20 μm to about 35 μm, and wherein the second length of each of the first slits is in the range of about 2800 μm to about 3500 μm.

16. The silicon crystallization mask of claim 2, wherein a distance between two adjacent first slits and a distance between two adjacent second slits are each in the range of about 2.5 μm to about 10 μm.

17. An apparatus to crystallize silicon, comprising:
a laser generator part configured to generate a laser beam; and
a silicon crystallization mask positioned to partially transmit the laser beam and partially block the laser beam, and to irradiate the partially transmitted laser beam on a substrate having amorphous silicon (a-Si) formed thereon, wherein the laser beam is to at least partially transform the amorphous silicon (a-Si) into poly silicon (poly-Si),
wherein the silicon crystallization mask comprises:
a plurality of first slits configured to transmit the laser beam, wherein the plurality of first slits are arranged along a first direction and are substantially parallel to one another, and wherein an imaginary central line of each of the first slits along a second direction perpendicular to the first direction divides the associated first slit into two substantially equal areas; and
a plurality of second slits configured to transmit the laser beam, the plurality of second slits separated from the plurality of first slits by a predetermined distance along the second direction, wherein the plurality of second slits are arranged along the first direction and are substantially parallel to one another, wherein an imaginary central line of each of the second slits along the second direction divides the associated second slit into two substantially equal areas, and wherein a central line of each of the plurality of second slits is offset from the central line of at least one adjacent first slit.

18. The apparatus of claim 17, further comprising:
a pulse width expansion part configured to expand a pulse width of the laser beam;
a beam equalizer optical part equalizing a density distribution of energy according to a position of the laser beam; and
a beam incidence part changing a size of the laser beam.

19. The apparatus of claim 18, further comprising:
a beam reflector part changing a direction of the laser beam.

20. A method for crystallizing silicon, comprising:
providing a substrate having amorphous silicon formed thereon;
irradiating a laser beam onto a partial area of the substrate through a mask and partially crystallizing the amorphous silicon;
moving the mask a predetermined distance with respect to the substrate; and
irradiating the laser beam onto another area of the substrate through the mask and partially crystallizing the amorphous silicon,
wherein the mask comprises:
first slits configured to transmit the laser beam and arranged substantially parallel to one another along a first direction, each of the first slits having an imaginary central line along the second direction dividing the first slit into substantially equal areas; and
second slits configured to transmit the laser beam and arranged substantially parallel to one another along the first direction, each of the second slits having an imaginary central line along the second direction dividing the second slit into substantially equal areas, and wherein the central lines of the first slits are offset from the central lines of the second slits

21. The method of claim 20, wherein a poly silicon (poly-Si) region formed by crystallizing the amorphous silicon has a crystal protrusion with a predetermined height in a center thereof, and the crystal protrusion is partially removed by re-irradiating the laser beam.
